(19) United States
(12) Patent Application Publication
(10) Pub. No.: US 2006/0166506 A1
(43) Pub. Date: Jul. 27, 2006

(54) Mask material for reactive ion etching, mask and dry etching method

(75) Inventors: Shuichi Okawa, Tokyo (JP); Kazuhiro Hattori, Tokyo (JP)

Correspondence Address: OLIFF & BERRIDGE, PLC, P.O. BOX 19928, ALEXANDRIA, VA, 22320, US

(73) Assignee: TDK CORPORATION, Tokyo (JP)

(21) Appl. No.: 10/553,677

(22) PCT Filed: Jun. 11, 2004
(86) PCT No.: PCT/JP04/08232

§ 371 Date: Oct. 17, 2005

(30) Foreign Application Priority Data
Jun. 30, 2003 (JP) 2003-188468

(51) Int. Cl. C23F 1/00; H01L 21/461; B44C 1/22; C03C 25/68; G03F 1/00

(52) U.S. Cl. 438/706; 216/58; 216/41; 216/47; 430/5

(57) ABSTRACT

To provide a dry etching method and the like that can precisely process regions targeted for etching of objects to be processed using reactive ion etching that uses carbon monoxide gas, to which a nitrogen-containing compound gas is added, as a reactive gas. A material containing silicon and tantalum is used to form a first mask layer 18 that covers a magnetic thin film layer 16.

### TECHNICAL FIELD

The present invention relates to a mask material for reactive ion etching, a mask, and a dry etching method used in processing of magnetic materials, for example.

### BACKGROUND ART

Reactive ion etching that uses as a reactive gas CO gas (carbon monoxide) to which a nitrogen-containing compound gas, such as NH₃ (ammonia) is added is known as a conventional microprocessing technology for magnetic material or the like (for example, see Japanese Patent Laid-Open Publication No. Hei 12-322710). This reactive ion etching can also be used to process non-magnetic materials such as Pt (platinum).

This reactive ion etching causes a transition metal, constituting for example, a magnetic material, and CO gas to react thereby generating a transition metal carbonyl compound with a small bonding energy and then uses a sputtering action to remove the generated transition metal carbonyl compound to process the magnetic material into a desired shape. The nitrogen-containing compound gas is added to suppress the decomposition of CO into C (carbon) and O (oxygen) to promote the generation of the transition metal carbonyl compound.

Mask materials comprising components such as Ti (titanium), Mg (magnesium), and Al (aluminum) are known as mask materials used for this reactive ion etching (for example, see Japanese Patent Laid-Open Publication No. Hei 11-92971). The same applicant as of the present application has proposed a mask material comprising a component such as Ta (tantalum) as a mask material with a considerably low etching rate for magnetic material and excellent etching selectivity (for example, see Japanese Patent Laid-Open Publication No. 2001-274144). In addition, reactive ion etching that uses a halogen containing gas as a reactive gas normally used in the semiconductor manufacturing field can be used for the technology that processes masks comprising these mask materials into a desired pattern.

Various types of microprocessing of magnetic materials or the like are thought to be possible using this type of dry etching method.

As an example, although the areal density of a magnetic recording medium, such as a hard disk, is remarkably improved by miniaturizing the magnetic particles which form the magnetic thin film, changing the material, improving the miniaturization of the head processing or the like, improvement methods including miniaturization of magnetic particles or the like have reached the limit and discrete type magnetic recording media in which the magnetic thin film is divided into a plurality of microscopic recording elements have been proposed as candidates for magnetic recording media that can attain even more improvements to the areal density (for example, see Japanese Patent Laid-Open Publication No. Hei 9-97419). In order to attain this kind of discrete type magnetic recording medium, processing of a microscopic region with a region width of 1 μm or less is required and it is thought that this type of microprocessing is also possible by means of using the dry etching method mentioned above.

However, even though microscopic patterns can be formed on magnetic materials or the like using the dry etching method described above, it was difficult to form a concave portion 102 with an ideally shaped vertical side wall 100 as shown in FIG. 10A and in reality a concave portion 106 with tapered side wall 104 was formed as shown in FIG. 10B and a certain deviation occurred between the desired processed shape and the actual processed shape. To explain in even more detail, during a dry etching process a part of the gas approaches the object to be processed at a slight inclination from the vertical direction. In this case, even if the end of the region targeted for etching is exposed from the mask 108, part of the end is shaded by the mask 108 with respect to the part of the gas. It is thought that because of this, the etching progress will be delayed more than other areas resulting in a concave portion forming with a tapered side wall. There is a tendency accompanying miniaturization of the regions targeted for etching for this type of deviation in the processing shape to have a relatively larger effect on the product characteristics increasing the need for dry etching technology that reduces the taper angle of the side wall (namely, forms the side wall nearly in vertical).

In addition, in order to dry etch an object to be processed, one or more masks are formed on the object and the mask is normally processed by dry etching to form grooves with tapered side walls. Therefore, the concave portion of the mask surface is transferred onto the object to be processed while sequentially narrowing the concave portion. If the concave portion becomes excessively narrow, the concave portion will be formed on the object to be processed with a V-shaped cross section of which both side walls are continuous and the etching will not make any progress thereby making it impossible to process the object up to the desired depth. For example, a V groove is formed shallower than the thickness of the magnetic thin film layer in the discrete type magnetic recording medium mentioned above thereby making it impossible to divide up the magnetic thin film layer.

Although this type of situation can be avoided if the taper angle of the concave portion side wall is took into consideration and form concave portions with sufficiently large widths on the surface of the mask, when the patterns are microscopic and the intervals between the concave portions are small, the concave portions on the surface will be continuous making it impossible to form each concave portion separately.

Even further, if the taper angle of the concave portion side wall on the mask is large, there is a problem of maintaining an accurate transfer of the pattern onto the object to be processed.

### DISCLOSURE OF INVENTION

The present invention was conceived in consideration of the above-described problems, and has an objective of providing a dry etching method or the like that can precisely process objects to be processed using reactive ion etching that uses carbon monoxide gas, to which a nitrogen-containing compound gas is added, as a reactive gas.

The present invention solved the problems mentioned above by means of using a material that contains silicon and tantalum as a mask material for reactive ion etching that uses carbon monoxide gas, to which a nitrogen-containing compound gas is added, as a reactive gas.

In processes leading to the present invention, the inventors discovered through trial and error testing of various materials as a mask material for dry etching that the processing shape easily changes depending on the setting conditions such as bias power when using reactive ion etching, that uses a halogen containing gas as a reactive gas, to process a mask material comprising silicon and tantalum.

As an example, if the bias power in reactive ion etching was reduced, the taper angle of the concave portion side wall formed on the mask was reduced. By only reducing the taper angle of the concave portion side wall of the mask in this manner, it is possible to process microscopic patterns of which concave portions are arranged in narrow intervals. In addition, reducing the taper angle of the concave portion side wall of the mask also makes it possible to improve the transfer accuracy of the pattern onto the object to be processed.

Although the reason why the processing shape of a mask changes depending on the setting conditions of the reactive ion etching in this manner is not always clear, by and large the following reasons are assumed.

Etching progresses due to a synergistic effect between physical actions such as ion collisions and chemical actions of reactive gases in reactive ion etching. Conventionally, reducing the gas pressure and increasing the bias power increased the linearity of the ions and inhibited the taper angle of the concave portion side wall. In other words, for the most part this controlled the physical action of reactive ion etching and inhibited the taper angle of the concave portion side wall. Improving the linearity of the ions by adjusting the gas pressure and bias power in this manner had already reached its limits however and all the ions approaching the object to be processed could not be directed in a completely vertical direction.

In contrast, since silicon reacts with a halogen containing reactive gas more easily than tantalum, etching of mask materials containing silicon and tantalum progresses easier using the chemical action of halogen containing gas than with tantalum by itself. Put another way, even if the physical action is inhibited to a certain extent, the etching will make sufficient progress. Since etching will progress isotropically through the use of a chemical action, it is thought that etching of areas shaded by a mask (other mask used to process the mask) will be facilitated and the taper angle of the side wall will become smaller.

Namely, the present invention has a completely different concept and composition compared to conventional technology in which it is common knowledge to inhibit the taper angle of the concave portion side wall by increasing the physical action of reactive ion etching and improving the linearity of the ions. It is thought that the taper angle of the concave portion side wall is reduced using a method that increases the chemical action while the physical action of reactive ion etching is inhibited. This is opposite from conventional reactive ion etching technology

Although silicon materials which do not contain tantalum also react easier with a halogen containing reactive gas than with tantalum by itself and the etching easily progresses, silicon materials which do not contain tantalum are not suitable for use as mask materials in reactive ion etching that uses carbon monoxide gas as a reactive gas because the etching progresses easily as well in this reactive ion etching

In contrast to this, materials which contain silicon and tantalum have sufficient etching resistance when using reactive ion etching that uses carbon monoxide gas as a reactive gas and are suitable for use as a mask material.

Furthermore, the inventors discovered that by controlling the ratio of silicon to the total number of atoms made up of the number of silicon atoms and the number of tantalum atoms to 50% or less, the materials which contain silicon and tantalum has the resistance against reactive ion etching that uses carbon monoxide gas as a reactive gas larger than tantalum itself. In other words, this makes it possible for the thickness of the mask to be made thinner and the areas shaded by the mask to be reduced. Accordingly, the taper angle of the concave portion side wall formed on the object to be processed can be reduced.

Namely, the present inventions as described below can solve the problems mentioned above.

(1) A mask material for reactive ion etching that uses carbon monoxide gas, to which a nitrogen-containing compound gas is added, as a reactive gas, the mask material for reactive ion etching characterized by containing silicon and tantalum.

(2) The mask material for reactive ion etching according to (1), characterized by containing either a compound of silicon and tantalum or a mixture of silicon and tantalum.

(3) The mask material for reactive ion etching according to (1) or (2), characterized by a layered body comprising a silicon based material layer that is formed from a material containing silicon in a layer shape and a tantalum based material layer that is formed from a material containing tantalum in a layer shape.

(4) The mask material for reactive ion etching according to any one of (1) to (3), characterized by containing at least one material from among an oxide that contains silicon and tantalum, a nitride that contains silicon and tantalum, a silicon oxide, a silicon nitride, a tantalum oxide, and a tantalum nitride.

(5) The mask material for reactive ion etching according to any one of (1) to (4), characterized by a ratio of a number of silicon atoms to a total number of atoms made up of the number of silicon atoms and a number of tantalum atoms being more than 0% and 50% or less.

(6) The mask material for reactive ion etching according to (5), characterized by the ratio of the number of silicon atoms to the total number of atoms made up of the number of silicon atoms and the number of tantalum atoms being more than 10% and 30% or less.

(7) A mask for reactive ion etching characterized by comprising the mask material for reactive ion etching as set forth in any one of (1) to (6).

(8) A dry etching method characterized by including: a mask forming step of forming a mask layer comprising the mask material for reactive ion etching as set forth in any one of (1) to (6) in a predetermined pattern on an object to be processed; and an object processing step for processing the object to be processed in a shape of the pattern through the use of reactive ion etching that uses carbon monoxide gas, to which a nitrogen-containing compound gas is added, as a reactive gas.

(9) The dry etching method according to (8) characterized in that the mask forming step is a step of: depositing a first mask layer on the object to be processed using the mask layer as the first mask layer; forming a second mask layer in the pattern on the first mask layer; and processing the first mask layer into the shape of the pattern through the use of reactive ion etching that uses a halogen containing gas as a reactive gas.

(10) The dry etching method according to claim 8 or 9 characterized by processing a magnetic material serving as the object to be processed.

### BRIEF DESCRIPTION OF DRAWINGS

FIG. 1 is a schematic sectional side view showing the configuration of a starting body of a specimen according to an exemplary embodiment of the present invention.

FIG. 2 is a schematic sectional side view showing the structure of a completed body of the specimen obtained by processing the same starting body as above.

FIG. 3 is a sectional side view that includes a block diagram partially schematically showing the structure of a reactive ion etching device used to process the same specimen as above.

FIG. 4 is a flowchart showing processing of the same specimen as above.

FIG. 5 is a sectional side view showing the shape of a specimen whose resist layer was divided into a pattern.

FIG. 6 is a schematic sectional side view showing the shape of a specimen whose second mask layer under a groove bottom surface is removed.

FIG. 7 is a schematic sectional side view showing the shape of a specimen whose first mask layer under the groove bottom surface is removed.

FIG. 8 is a schematic sectional side view showing the shape of a specimen whose magnetic thin film is divided.

FIG. 9 is a graph showing the relationship between the ratio of silicon contained in the material of the first mask layer and the selectivity of the etching.

FIG. 10A is a schematic sectional side view showing the shape of the ideal concave portion and FIG. 10B is a schematic sectional side view showing the shape of the actual concave portion.

### BEST MODE FOR CARRYING OUT THE INVENTION

In the following a preferred exemplary embodiment of the present invention will be described with reference to the accompanying drawings.

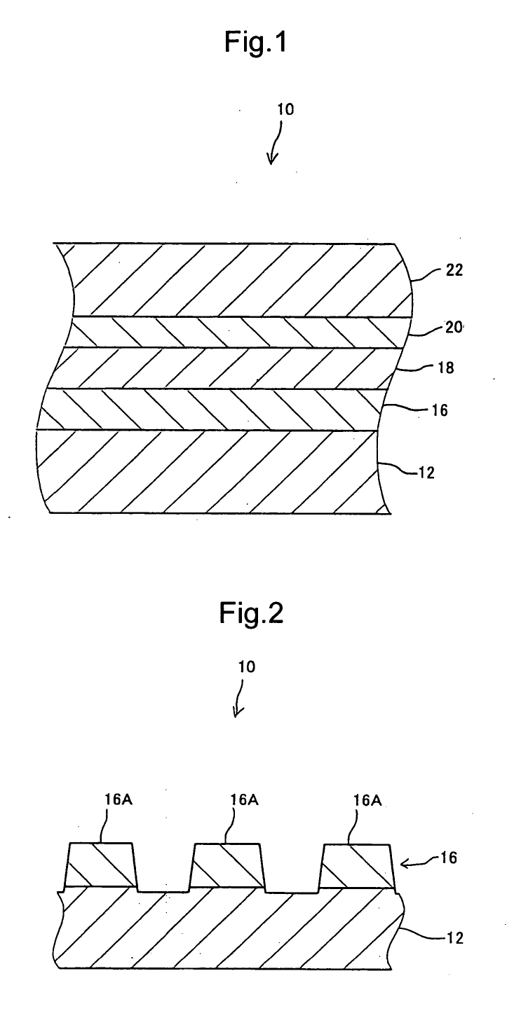

This exemplary embodiment performs processing, such as dry etching, on a starting body of a specimen as shown in FIG. 1 to process a magnetic thin film (magnetic material) into a predetermined line-and-space pattern as shown in FIG. 2 and is characterized by a mask material that covers the magnetic thin film layer and a processing process of a mask. Descriptions of other configurations will be suitably omitted when identical to a conventional example.

The starting body of specimen 10 has a configuration formed by a magnetic thin film layer 16, a first mask layer 18, a second mask layer 20, and a resist layer 22, which are formed over a glass substrate 21 in that order.

The magnetic thin film layer 16 has a thickness of 5 to 30 nm and the material thereof is a CoCr (cobalt chromium) alloy.

The first mask layer 18 has a thickness of 5 to 50 nm and the material thereof is a mixture of silicon and tantalum. The ratio of the number of silicon atoms to the number of atoms made up of the total number of silicon atoms and the number of tantalum atoms is approximately 20% (10% or more as well as 30% or less).

The second mask layer 20 has a thickness of 5 to 30 nm and the material thereof is Ni (nickel).

The resist layer 22 has a thickness of 30 to 300 nm and the material thereof is an electron beam resist (ZEP520 by Zeon Corporation).

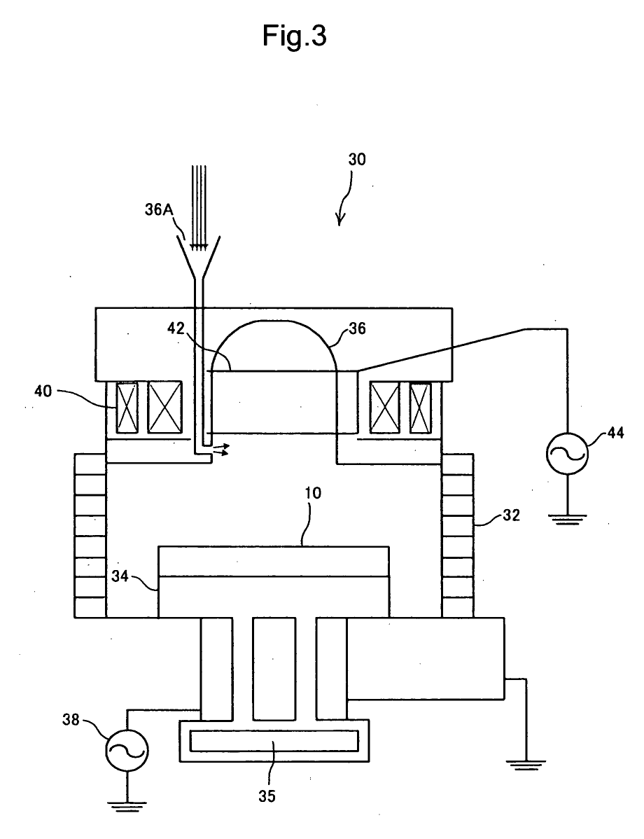

The processing of specimen 10 is performed using the reactive ion etching device as shown in FIG. 3.

The reactive ion etching device 30 is a helicon wave plasma system device and is equipped with a diffusion chamber 32, an ESC (electrostatic chuck) stage electrode 34 used to set specimen 10 inside the diffusion chamber 32, and a quartz bell jar 36 used to generate plasma.

A bias power supply 38 that applies a bias voltage is connected to the ESC stage electrode 34. The bias voltage is an alternating current power supply with a frequency of 1.6 MHz.

The quartz bell jar 36 opens inside the diffusion chamber 32 at its lower end and an gas supply hole 36A is led close to the lower end to supply a reactive gas. An electromagnetic coil 40 and an antenna 42 are provided at the periphery of the quartz bell jar 36 and a plasma generating power supply 44 is connected to the antenna 42. The plasma generating power supply 44 is an alternating current power supply with a frequency of 13.56 MHz.

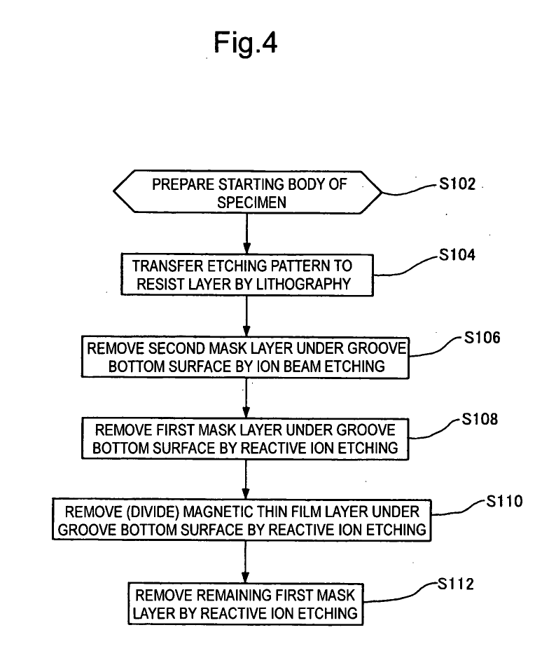

The processing method for specimen 10 will now be described following the flowchart shown in FIG. 4.

Initially, prepare the starting body of specimen 10 shown in FIG. 1 (S102). The starting body of specimen 10 is obtained by forming over glass substrate 12 the magnetic thin film layer 16, the first mask layer 18, and the second mask layer 20, in that order, using a sputtering method and applying the resist layer 22 using a spin coat method.

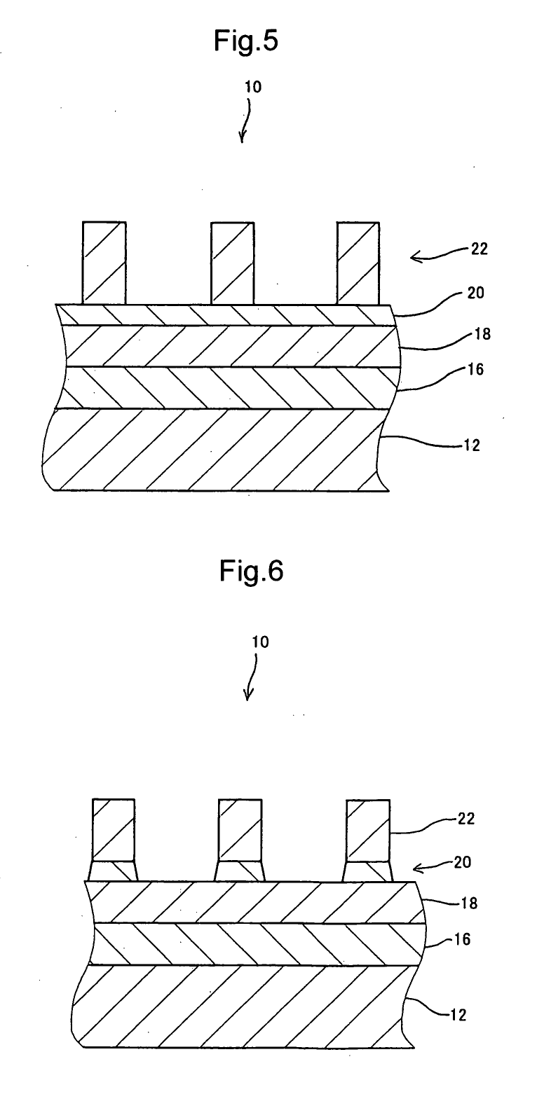

The resist layer 22 of this starting body of specimen 10 is exposed using an electron beam exposure device (not shown in the drawings) and developed for 5 minutes at room temperature using a ZED-N50 (Zeon Corporation) to remove the exposed area, thereby forming a number of grooves at microscopic intervals as shown in FIG. 5 (S104).

Next, an ion beam etching device (not shown in the drawings), that uses Ar (argon) gas is used to remove the second mask layer 20 under the groove bottom surface as shown in FIG. 6 (S106). Consequently, a groove narrowed toward the first mask layer 18 is formed and the side wall of the second mask layer 20 forms a tapered shape slightly inclined from the vertical direction. The region of resist layer 22 outside the groove is also slightly removed during this process.

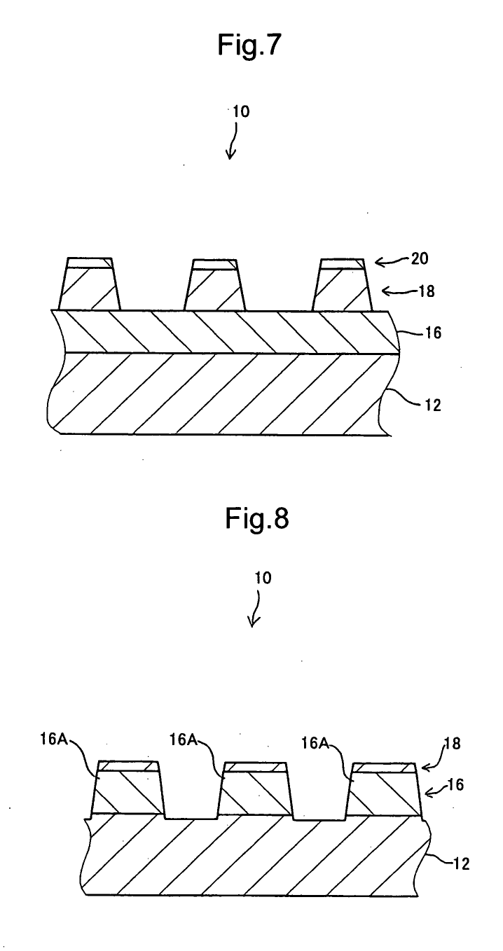

Then, the reactive ion etching device 30 is used to remove the first mask layer 18 under the groove bottom surface as shown in FIG. 7 by means of reactive ion etching that uses CF₄ gas or SF₆ gas (halogen containing reactive gas) (S108).

In more detail, the specimen 10 is placed on and secured to the ESC stage electrode 34 and a bias voltage is applied. When the electromagnetic coil 40 generates a magnetic field and the antenna 42 radiates a helicon wave, the helicon wave propagates along the magnetic field and a high-density plasma generates inside the quartz bell jar 36. When CF₄ gas or SF₆ gas is supplied from the gas supply hole 36A, radicals diffuse inside the diffusion chamber 32, adhere to the surface of the first mask layer 18, and then react therewith. Ions are induced by the bias voltage and collide with the specimen 10 thereby removing the surface of first mask layer 18. During this process, the bias power from the bias power supply 38 is adjusted to a low level within a range that does not limit the etching of the first mask layer 18 excessively. Since the first mask layer 18 contains silicon, a material that can easily react with a halogen containing reactive gas, the bias power can be adjusted to a low level to that extent.

Consequently, a groove narrowed toward the magnetic thin film layer 16 is formed and a side wall with a tapered shape slightly inclined from the vertical direction is formed on the first mask layer 18. However, since the bias power is adjusted to a low level, the taper angle of the side wall of the first mask layer 18 is controlled to be kept small. Here, the region of the resist layer 22 outside the groove is completely removed. The region of the second mask layer 20 outside the groove is also partially removed although a certain amount remains.

Next, as shown in FIG. 8, the magnetic thin film layer 16 under the groove bottom surface is removed using reactive ion etching device 30 or another reactive ion etching device with a similar construction (S110).

Describing an example when using the reactive ion etching device 30 in detail, by supplying CO gas and NH₃ gas from gas supply hole 36A instead of CF₄ gas or SF₆ gas used in reactive ion etching of the first mask layer 18 mentioned above, radicals diffuse inside the diffusion chamber 32 and the surface of the magnetic thin film layer 16 is carbonylated. Ions are induced by the bias voltage and remove the surface of the carbonylated magnetic thin film layer 16.

Consequently, a groove narrowed toward the substrate 12 is formed and a side wall with a tapered shape is formed slightly inclined from the vertical direction.

Here, the material of the first mask layer 18 is a mixture of silicon and tantalum and the ratio of the number of silicon atoms to the number of atoms made up of the total number of silicon atoms and the number of tantalum atoms is approximately 20% (10% or more as well as 30% or less). Since the etching rate is low (high etching resistance) against the reactive ion etching that uses CO gas and NH₃ gas (described later) as a reactive gas, the first mask layer 18 is formed thin to that extent. Consequently, the portion shaded by the first mask layer 18 is small for the gas that is approaching at a slight inclination from the vertical direction and the taper angle of the side wall of the magnetic thin film layer 16 is restricted to be small to that extent. In other words, even if the pattern is microscopic, the magnetic thin film layer 16 is precisely processed and the magnetic thin film layer 16 is divided into a plurality of recording elements 16A.

The region of the second mask layer 20 outside the groove is completely removed by this reactive ion etching. Part of the first mask layer 18 outside the groove is also removed although a certain amount remains on the surface of the recording elements.

Next, as shown in FIG. 8, the first mask layer 18 remaining on the surface of the recording elements 16A is completely removed by reactive ion etching that uses CF₄ gas or SF₆ gas (S112). Alternatively, the first mask layer 18 remaining on the surface of the recording elements can be removed by a reactive ashing device that uses CF₄ gas or SF₆ gas (not shown in the drawings).

The processing of the specimen 10 is completed by this process.

As described above, the thickness of the first mask layer 18 can be made thinner and the recording elements 16A can be formed with the side wall having small taper angle by means of using a material comprising silicon and tantalum with low etching rates for reactive ion etching that uses a reactive gas comprising CO gas and NH₃ gas as the material of the first mask layer 18 that covers the magnetic thin film layer 16.

In addition, through the use of a material comprising silicon and tantalum, it is also possible to adjust the setting conditions of reactive ion etching, that uses a halogen containing reactive gas, to reduce the taper angle of the side wall of the first mask layer 18 itself and thereby improve the transfer accuracy of the pattern.

Furthermore, a microscopic pattern with a small groove pitch can be transferred to the magnetic thin film layer 16 because it is possible to reduce the taper angle of the side wall of the recording elements 16A and the taper angle of the side wall of the first mask layer 18.

Although CO gas, to which NH₃ gas is added, is used as a reactive gas for the reactive ion etching that processes the magnetic thin film layer 16 in this exemplary embodiment, the present invention is not limited to this. The magnetic thin film layer 16 can also be processed using CO gas as a reactive gas, wherein another nitrogen-containing compound gas, such as amine gas that has an effect to suppress the decomposition of CO, is added to this CO gas.

Although CF₄ gas or SF₆ gas is used as reactive gas for the reactive ion etching to process the first mask layer 18 in this exemplary embodiment, the present invention is not limited to this. Another halogen containing gas can be used to process first mask layer 18.

Although the reactive ion etching device 30, that processes the magnetic thin film layer 16 and the first mask layer 18, is a helicon wave plasma system device in this exemplary embodiment, the present invention is not limited to this. Reactive ion etching devices using other systems such as a parallel plate system, magnetron system, two cycle energization system, ECR (Electron Cyclotron Resonance) system, or ICP (Inductively Coupled Plasma) system can also be used.

Although the resist layer 22 and the second mask layer 20 are formed over the first mask layer 18 and then an electron beam exposure device and an ion beam etching are used to form the second mask layer 20 into a predetermined pattern, there are no particular restrictions on the mask layer that is formed over the first mask layer 18, the material of the resist layer, the processing method, and the number of layers if a second mask layer, that has etching resistance against halogen containing reactive gases, can be formed on the first mask layer 18 with high precision. For example, a nano-imprinting method can be used in place of an electron beam exposure device as a method to form grooves at microscopic intervals on the resist layer 22.

Although the first mask layer 18 has a ratio of the number of silicon atoms to the total number of atoms made up of the number of silicon atoms and the number of tantalum atoms being approximately 20%, the present invention is not limited to this. If the mask material is a mixture of silicon and tantalum, the processing shape can be controlled and the taper angle formed on the mask can be reduced by adjusting the setting conditions of the reactive ion etching that uses a halogen containing reactive gas in spite of their ratio.

As described later, if the ratio of the number of silicon atoms to the total number of atoms made up of the number of silicon atoms and the number of tantalum atoms is 50% or less, the etching rate with respect to reactive ion etching that uses CO gas and NH₃ gas as a reactive gas can be lower than tantalum itself (higher etching resistance). The etching rate can be lowered much more than tantalum itself by keeping the ratio of the number of silicon atoms at 10% or more and 30% or less. This is especially preferable.

Although the material of the first mask layer 18 is a mask material comprising a mixture of silicon and tantalum, another silicon based material such as silicon dioxide or silicon nitride can be used in place of the silicon in this embodiment. In addition, another tantalum based material such as tantalum dioxide or tantalum nitride can be used in place of tantalum. A compound containing silicon and tantalum can also be used. A layered body comprising a layer of silicon based material and a layer of tantalum based material can also be used. When using a layered body, the layer of silicon based material can contain tantalum based material and the layer of tantalum based material can contain silicon based material. For this case as well, the processing shape of the mask can be controlled and the taper angle formed on the mask can be reduced by adjusting the setting conditions of the reactive ion etching that uses a halogen containing reactive gas. Moreover, for this case as well, the etching rate with respect to reactive ion etching that uses CO gas and NH₃ gas as a reactive gas can be lowered more than tantalum itself.

Although the specimen 10 is a test specimen with a composition in which the magnetic thin film layer 16 is formed directly on the glass substrate 12 in this exemplary embodiment, it goes without saying that the present invention can also be applied to various recording media and devices configured to have magnetic materials, such as magnetic disks including hard disks, magnetic optical disks, magnetic tapes, and magnetic heads.

Although the material of the magnetic thin film layer 16 is a CoCr alloy in this exemplary embodiment, the present invention is not limited to this. For example, a mask material comprising a mixture of silicon and tantalum is suitable as a mask material to process magnetic materials with other qualities such as other alloys containing iron group elements (Co, Fe (iron), Ni) and a layered body of these alloys.

Although mask materials comprising a mixture of silicon and tantalum are used to process magnetic materials in this exemplary embodiment, the present invention is not limited to this. Mask materials comprising a mixture of silicon and tantalum are suitable as mask materials to process non-magnetic materials such as Pt that can be processed by reactive ion etching that uses CO gas and NH₃ gas as a reactive gas.

### EXAMPLE 1

As described in the exemplary embodiment above, the ratio of the number of silicon atoms to the total number of atoms made up of the number of silicon atoms and the number of tantalum atoms was approximately 20%. In other words, the composition ratio of the number of tantalum atoms and the number of silicon atoms was approximately 4:1.

The thickness of the magnetic thin film layer 16 was approximately 25 nm, the thickness of the first mask layer 18 was approximately 20 nm, the thickness of the second mask layer 20 was approximately 15 nm, and the thickness of the resist layer 22 was approximately 130 nm. Two starting bodies of specimen 10 were produced.

Grooves were formed with vertical side walls in the resist layer 22 when exposing and developing patterns with pitches of approximately 120 nm and a line-and-space ratio of approximately 1:1 (namely, patterns whose line width and space width each were approximately 60 nm).

Grooves with tapered side walls were formed in the second mask layer 20 and the space width of the groove bottom surface was approximately 55 nm (line width of approximately 65 nm).

Grooves with tapered side walls were also formed in first mask layer 18. The bias power had different values for the two specimens and the values were adjusted to 150 W and 75 W, respectively while the source power was constantly maintained at 1,000 W during the processing of the first mask layer 18. When the bias power was 150 W, the space width of the groove bottom surface was approximately 23 nm. In contrast, when the bias power was 75 W, the space width of the groove bottom surface was approximately 38 nm. Incidentally, a stage electrode of the reactive ion etching device had a diameter of 6 inches.

Grooves with tapered side walls were also formed in the magnetic thin film layer 16. The source power was constantly maintained at 1,000 W and the bias power constantly maintained at 250 W for either of the two specimens during the processing of the magnetic thin film layer 16. When the space width of the bottom surface of the first mask layer 18 was 23 nm, the space width of the bottom surface of the magnetic thin film layer 16 was approximately 15 nm. In contrast, when the space width of the bottom surface of the first mask layer 18 was 38 nm, the space width of the bottom surface of the magnetic thin film layer 16 was approximately 29 nm.

### EXAMPLE 2

Compared to the example 1 described above, the ratio of the number of silicon atoms to the total number of atoms made up of the number of silicon atoms and the number of tantalum atoms was approximately 80%. In other words, the composition ratio of the number of tantalum atoms and the number of silicon atoms was approximately 1:4. The other conditions were the same as the example 1 and two starting bodies of specimen 10 were produced. Grooves with tapered side walls were formed in the second mask layer 20 and the space width of the bottom surface was approximately 55 nm, in like manner to the example 1, (line width was approximately 65 nm) when the resist layer 22 and the second mask layer 20 were processed.

Furthermore, in like manner to the example 1, the bias power had different values for the two specimens and values were adjusted to 150 W and 75 W, respectively while the source power was constantly maintained at 1,000 W during the processing of the first mask layer 18. When the bias power was 150 W, the space width of the groove bottom surface was approximately 15 nm. In contrast, when the bias power was 75 W, the space width of the groove bottom surface was approximately 45 nm.

Grooves with tapered side walls were also formed in the magnetic thin film layer 16. When the space width of the bottom surface of the first mask layer 18 was 15 nm, the space width of the bottom surface of the magnetic thin film layer 16 was approximately 7 nm. In contrast, when the space width of the bottom surface of the first mask layer 18 was 45 nm, the space width of the bottom surface of the magnetic thin film layer 16 was approximately 36 nm.

### COMPARATIVE EXAMPLE

Compared to the example 1 described above, the material of the first mask layer 18 did not contain silicon and was almost pure tantalum. The other conditions were the same as the example 1 and two starting bodies of specimen 10 were produced. Grooves with tapered side walls were formed in the second mask layer 20 and the space width of the bottom surface was approximately 55 nm (line width was approximately 65 nm) when the resist layer 22 and the second mask layer 20 were processed.

In like manner to example 1, the bias power had different values for the two specimens and values were adjusted to 150 W and 75 W, respectively while the source power was constantly maintained at 1,000 W during the processing of the first mask layer 18. When the bias power was 150 W, the space width of the bottom surface was approximately 25 nm. In contrast, when the bias power was 75 W, the space width of the bottom surface was approximately 25 nm.

The results of the example 1, the example 2, and the comparative example are compared and shown in Table 1.

TABLE 1

| | Example 1 | | Example 2 | | Comparative Example | |
|---|---|---|---|---|---|---|
| Material of the second mask layer | Ni | | Ni | | Ni | |
| Material of the first mask layer | Ta: Si = 4:1 | | Ta: Si = 1:4 | | Ta | |
| Space width of the bottom surface | 60 | | 60 | | 60 | |
| of the resist layer (nm) | | | | | | |
| Space width of the bottom surface | 55 | | 55 | | 55 | |
| of the second mask layer (nm) | | | | | | |
| Bias power during the processing of | 150 | 75 | 150 | 75 | 150 | 75 |
| the first mask layer (W) | | | | | | |
| Space width of the bottom surface | 23 | 38 | 15 | 45 | 25 | 25 |
| of the first mask layer (nm) | | | | | | |
| Space width of the bottom surface | 15 | 29 | 7 | 36 | — | — |
| of the magnetic thin film layer (nm) | | | | | | |

Compared to the comparative example, it was possible to produce the processing shape of the magnetic thin film layer 16 with a side wall of a small taper angle in the example 1 and the example 2. Furthermore, it was confirmed that the taper angle of the side wall became smaller by adjusting the bias power in the example 1 and the example 2. In contrast, it was confirmed that the space width did not change by a certain amount even if the bias power was adjusted in the comparative example.

### EXAMPLE 3

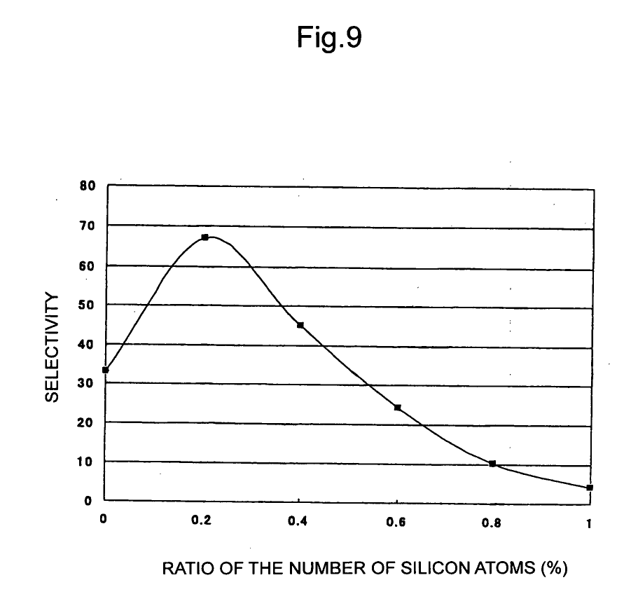

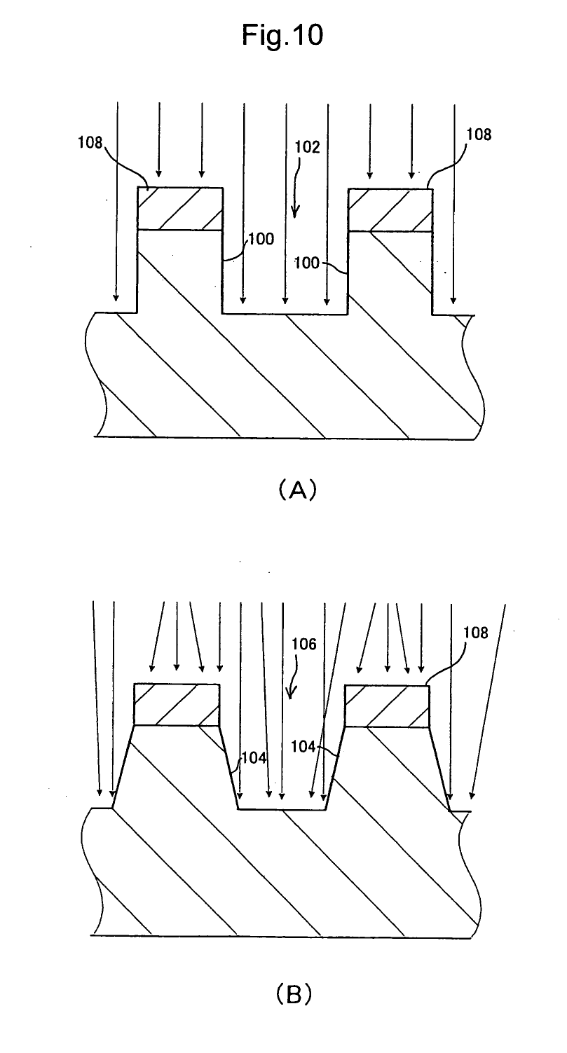

A result as shown in FIG. 9 was obtained in which the first mask layer 18 was formed using a variety of mask materials with different ratios of the number of silicon atoms to the total number of atoms made up of the number of silicon atoms and the number of tantalum atoms and the selectivity of the first mask layer 18 was measured during reactive ion etching that uses CO gas and NH₃ gas as a reactive gas. Here, the selectivity is a value obtained by dividing the etching speed of the magnetic thin film layer 16 by the etching speed of the first mask layer 18.

As shown in FIG. 9, it was confirmed that if the ratio of the number of silicon atoms to the total number of atoms made up of the number of silicon atoms and the number of tantalum atoms is larger than 0% and also 50% or less, the selectivity will become larger than 33 which is the selectivity of a mask whose material is pure tantalum. This is a preferred ratio when the material is used as a mask material.

It was also confirmed that if the ratio of the number of silicon atoms to the total number of atoms made up of the number of silicon atoms and the number of tantalum atoms is 5% or more as well as 40% or less, the selectivity will become 45 or more which is even more preferable. In particular, if the ratio of the number of silicon atoms is 10% or more as well as 30% or less, a selectivity of 50 or more will be obtained which is even more preferable. The selectivity is approximately 66.7 as a maximum value when the ratio of the number of silicon atoms is approximately 20%. This is especially preferable value.

If the ratio of the number of silicon atoms to the total number of atoms made up of the number of silicon atoms and the number of tantalum atoms exceeds 80%, there is a tendency for the area in the vicinity of the upper end of the side wall of recording elements 16A to be excessively removed. Even if the pattern, the film thickness of the mask, and the setting conditions of the reactive ion etching are adjusted, there is a case where the recording elements 16A will be processed in a rounded shape and it will become difficult to obtain desired processing. Because of this, the ratio of the number of silicon atoms is preferably 80% or less.

### INDUSTRIAL APPLICABILITY

As described above, the present invention has the effect of making it possible to precisely process regions targeted for etching of objects to be processed using reactive ion etching that uses carbon monoxide gas, to which a nitrogen-containing compound gas is added, as a reactive gas.

1. A mask material for reactive ion etching that uses carbon monoxide gas, to which a nitrogen-containing compound gas is added, as a reactive gas,
the mask material for reactive ion etching characterized by containing silicon and tantalum.

2. The mask material for reactive ion etching according to claim 1, characterized by containing either a compound of silicon and tantalum or a mixture of silicon and tantalum.

3. The mask material for reactive ion etching according to claim 1, characterized by a layered body comprising a silicon based material layer that is formed from a material containing silicon in a layer shape and a tantalum based material layer that is formed from a material containing tantalum in a layer shape.

4. The mask material for reactive ion etching according to claim 1, characterized by containing at least one material from among an oxide that contains silicon and tantalum, a nitride that contains silicon and tantalum, a silicon oxide, a silicon nitride, a tantalum oxide, and a tantalum nitride.

5. The mask material for reactive ion etching according to claim 1, characterized by a ratio of a number of silicon atoms to a total number of atoms made up of the number of silicon atoms and a number of tantalum atoms being more than 0% and 50% or less.

6. The mask material for reactive ion etching according to claim 5, characterized by the ratio of the number of silicon atoms to the total number of atoms made up of the number of silicon atoms and the number of tantalum atoms being more than 10% and 30% or less.

7. A mask for reactive ion etching characterized by comprising the mask material for reactive ion etching as set forth in claim 1.

8. A dry etching method characterized by including: a mask forming step of forming a mask layer comprising the mask material for reactive ion etching as set forth in claim 1 in a predetermined pattern on an object to be processed; and an object processing step for processing the object to be processed in a shape of the pattern through the use of reactive ion etching that uses carbon monoxide gas, to which a nitrogen-containing compound gas is added, as a reactive gas.

9. The dry etching method according to claim 8 characterized in that the mask forming step is a step of: depositing a first mask layer on the object to be processed using the mask layer as the first mask layer; forming a second mask layer in the pattern on the first mask layer; and processing the first mask layer into the shape of the pattern through the use of reactive ion etching that uses a halogen containing gas as a reactive gas.

10. The dry etching method according to claim 8 characterized by processing a magnetic material serving as the object to be processed.

11. The mask material for reactive ion etching according to claim 2, characterized by a layered body comprising a silicon based material layer that is formed from a material containing silicon in a layer shape and a tantalum based material layer that is formed from a material containing tantalum in a layer shape.

12. The mask material for reactive ion etching according to claim 2, characterized by containing at least one material from among an oxide that contains silicon and tantalum, a nitride that contains silicon and tantalum, a silicon oxide, a silicon nitride, a tantalum oxide, and a tantalum nitride.

13. The mask material for reactive ion etching according to claim 3, characterized by containing at least one material from among an oxide that contains silicon and tantalum, a nitride that contains silicon and tantalum, a silicon oxide, a silicon nitride, a tantalum oxide, and a tantalum nitride.

14. The mask material for reactive ion etching according to claim 2, characterized by a ratio of a number of silicon atoms to a total number of atoms made up of the number of silicon atoms and a number of tantalum atoms being more than 0% and 50% or less.

15. The mask material for reactive ion etching according to claim 3, characterized by a ratio of a number of silicon atoms to a total number of atoms made up of the number of silicon atoms and a number of tantalum atoms being more than 0% and 50% or less.

16. A mask for reactive ion etching characterized by comprising the mask material for reactive ion etching as set forth in claim 2.

17. A mask for reactive ion etching characterized by comprising the mask material for reactive ion etching as set forth in claim 3.

18. A dry etching method characterized by including: a mask forming step of forming a mask layer comprising the mask material for reactive ion etching as set forth in claim 2 in a predetermined pattern on an object to be processed; and an object processing step for processing the object to be processed in a shape of the pattern through the use of reactive ion etching that uses carbon monoxide gas, to which a nitrogen-containing compound gas is added, as a reactive gas.

19. A dry etching method characterized by including: a mask forming step of forming a mask layer comprising the mask material for reactive ion etching as set forth in claim 3 in a predetermined pattern on an object to be processed; and an object processing step for processing the object to be processed in a shape of the pattern through the use of reactive ion etching that uses carbon monoxide gas, to which a nitrogen-containing compound gas is added, as a reactive gas.

20. The dry etching method according to claim 18 characterized by processing a magnetic material serving as the object to be processed.
